(19) United States
(12) Patent Application Publication
(10) Pub. No.: US 2009/0107402 A1
(43) Pub. Date: Apr. 30, 2009

(54) DEPOSITION APPARATUS AND CLEANING METHOD THEREOF

(75) Inventors: Tae-Young NAM, Seoul (KR); Tae-Ho KIM, Gyeonggi-do (KR); Jung-Il AHN, Gyeonggi-do (KR); Yun-Jin LEE, Gyeonggi-do (KR); Sang-Gon LEE, Gyeonggi-do (KR); Chung-Guen HAN, Gyeonggi-do (KR); Byung-Ho AHN, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/262,074

(22) Filed: Oct. 30, 2008

(30) Foreign Application Priority Data
Oct. 31, 2007 (KR) 2007-0110316

(51) Int. Cl. C23C 16/44

(52) U.S. Cl. 118/726

(57) ABSTRACT

A deposition apparatus including a vaporizer; a chemical supplier; a pipe line coupled between the vaporizer and the chemical supplier; and a solvent supplier coupled to the pipe line.

A method of cleaning a deposition apparatus including putting a solvent into a vaporizer; cleaning the vaporizer by impregnating the vaporizer with the solvent; and removing contaminated liquid which remains after cleaning the vaporizer.

### CROSS-REFERENCE TO RELATED APPLICATION

This application claims the benefit of Korean Patent Application No. 10-2007-0110316, filed Oct. 31, 2007, the contents of which is hereby incorporated herein by reference in its entirety.

### BACKGROUND

1. Technical Field

Example embodiments relate to a deposition apparatus and a cleaning method thereof, and more specifically, to an atomic layer deposition apparatus and a cleaning method thereof, which can remove particles, powder, and clogging occurring in a vaporizer and the peripheral devices thereof.

2. Description of Related Art

In recent times, a deposition method has been widely used as a technique for forming a thin film of a semiconductor device. The deposition method is a technique in which sources are alternately and repeatedly supplied to a substrate to deposit an atomic-layer thin film. In a semiconductor deposition process, which is a core process for forming a high k film, polymer chemicals can be used.

### SUMMARY

An embodiment includes a deposition apparatus including a vaporizer; a chemical supplier; a pipe line coupled between the vaporizer and the chemical supplier; and a solvent supplier coupled to the pipe line.

Another embodiment includes a method of cleaning a deposition apparatus including putting a solvent into a vaporizer; cleaning the vaporizer by impregnating the vaporizer with the solvent; and removing contaminated liquid which remains after cleaning the vaporizer.

Another embodiment includes an atomic layer deposition (ALD) apparatus including a reaction chamber configured to deposit a thin film on a substrate; a vaporizer coupled to the reaction chamber through a first pipe line to vaporize chemicals and to supply the vaporized chemicals to the reaction chamber; a chemical supplier coupled to the vaporizer through a second pipe line to supply chemicals to the vaporizer; and a solvent supplier coupled to the vaporizer through a third pipe line to clean the vaporizer by impregnating the vaporizer with a solvent after a thin film deposition process.

### BRIEF DESCRIPTION OF THE DRAWINGS

Embodiments are described in further detail below with reference to the accompanying drawings. It should be understood that various aspects of the drawings can have been exaggerated for clarity:

FIG. 1 is a diagram showing the construction of a deposition apparatus according to an embodiment;

FIG. 2 is a flow chart sequentially showing a method of cleaning the deposition apparatus according to an embodiment;

FIG. 3 is a graph showing an experiment for selecting an optimal solvent in the method of cleaning the deposition apparatus according to an embodiment;

FIG. 4 is a graph showing the concentration of Zr versus the number of cleanings in the method of cleaning the deposition apparatus according to an embodiment;

FIG. 5 is a graph illustrating a pressure change before and after the cleaning process in the method of cleaning the deposition apparatus according to an embodiment; and

FIGS. 6A and 6B are graphs comparing the flow rate of chemicals in the related art with the flow rate of chemicals in an embodiment.

### DETAILED DESCRIPTION OF THE EMBODIMENTS

Embodiments will now be described more fully with reference to the accompanying drawings in which some example embodiments are shown. In the drawings, the thicknesses of layers and regions can be exaggerated for clarity.

Although embodiments will be described with respect to a deposition apparatus, embodiments are not limited to a deposition apparatus, and can be applied to all industrial fields using a large quantity of chemicals which have a viscosity characteristic that can result in deposition of particles and/or powder, clogging, can be vulnerable to heat and pressure, or the like.

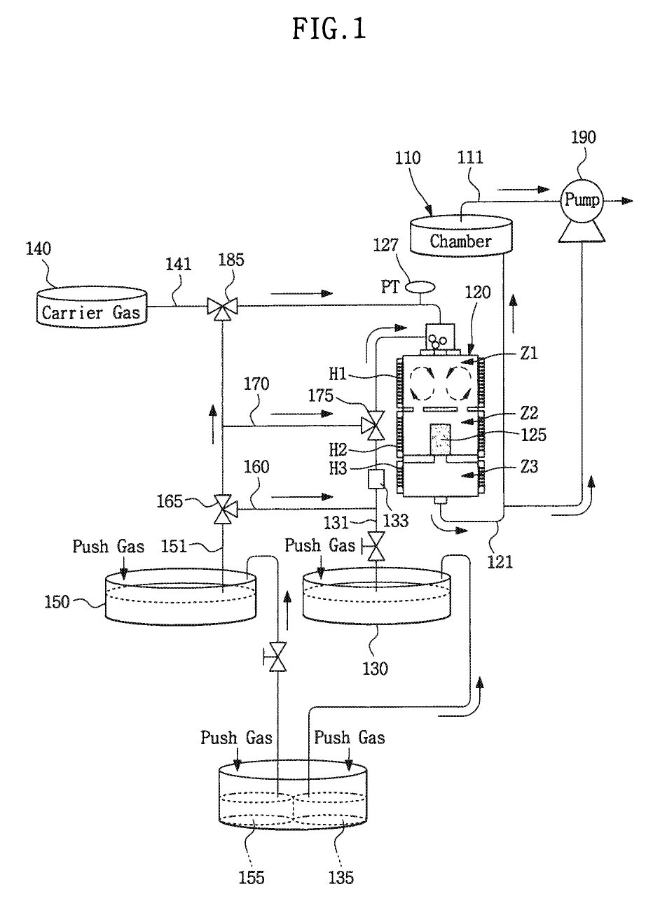

FIG. 1 is a diagram showing the construction of a deposition apparatus according to an embodiment. The deposition apparatus 100 according to an embodiment can include a reaction chamber 110 for depositing a thin film on a substrate (not shown); a vaporizer 120 which is coupled to the reaction chamber 110 through a pipe line 121 to vaporize chemicals to supply to the reaction chamber 110; a chemical supplier 130 which is coupled to the vaporizer 120 through a pipe line 131 to supply chemicals to the vaporizer 120; a carrier gas supplier 140 which is coupled to the vaporizer 120 through a pipe line 141 to supply carrier gases to the vaporizer 120; and a solvent supplier 150 which is coupled to the vaporizer 120 through a pipe line 151, to cleans the vaporizer 120 by impregnating the vaporizer 120 with a solvent and constantly maintaining the cleaning temperature of the vaporizer 120, after a thin film deposition process. For example, the deposition apparatus 100 may be an atomic layer deposition (ALD) apparatus.

In an embodiment, the reaction chamber 110 can be a device configured to receive a source to repeatedly supply the received source to a substrate (not shown) disposed in the reaction chamber 110, thereby depositing an atomic-layer thin film. In a semiconductor deposition process, a core process for manufacturing a high k film, a liquid source such as TMA, TEMAHf, or TEMAZr can be used. The vaporizer 120 can serve to vaporize such a liquid source to supply the vaporized source to the reaction chamber 110. Although particular examples of a source are given, the source to be received by the reaction chamber can be different from those described above.

According to the deposition process, since a thin film can be formed by only the chemical reaction on a substrate surface, a thin film with a substantially uniform thickness can be grown regardless of irregularities on the substrate surface. Further, since the deposition thickness of the film is not proportional to a deposition time but is proportional to the number of material supply periods, it is possible to precisely control the thickness of a film to be formed.

The chemical supplier 130 can be coupled to the vaporizer 120 through the pipe line 131 to supply chemicals to the vaporizer 120. A flow-rate controller 133 can be provided in the pipe line 131 of the chemical supplier 130.

The carrier gas supplier 140 can be coupled to the vaporizer 120 through the pipe line 141. Carrier gases such as nitrogen or argon, supplied by the carrier supplier 140, can serve to supply a precursor dissolved in a solvent such as ethanol to the vaporizer 120 through the pipe line 141. A pressure sensor 127 for measuring the internal pressure of the vaporizer 120 can be provided at the end of the pipe line 141.

The chemical supplier 130 can be coupled to a chemical refill unit 135. The solvent supplier 150 can be coupled to a solvent refill unit 155.

Between the pipe line 151 of the solvent supplier 150 and the pipe line 131 of the chemical supplier 130, a pipe line 160 for cleaning the flow-rate controller can be provided to connect the pipe lines 151 and 131.

A first three-way valve 165 can be provided at an intersection between the pipe line 151 of the solvent supplier 150 and the pipe line 160 for cleaning the flow-rate controller 133. A solvent supplied from the solvent supplier 150 can selectively pass through the flow-rate controller 133 via the pipe line 160 by the first three-way valve 165, thereby cleaning the flow-rate controller 133.

Between the pipe line 151 of the solvent supplier 150 and the pipe line 131 of the chemical supplier 130, a pipe line 170 for cleaning the vaporizer can be provided to connect the pipe lines 151 and 131. At an intersection between the pipe line 131 of the chemical supplier 130 and the pipe line 170 for cleaning the vaporizer, a second three-way valve 175 can be provided. A solvent supplied from the solvent supplier 150 can selectively pass through the pipe line 170 by the second three-way valve 175 to impregnate the vaporizer 120, thereby cleaning the vaporizer 120.

At an intersection between the pipe line 151 of the solvent supplier 150 and the pipe line 141 of the carrier gas supplier 140, a third three-way valve 185 can be provided. A solvent supplied from the solvent supplier 150 can selectively pass through the pipe line 141 of the carrier gas supplier 140 by the third three-way valve 185, thereby cleaning the pipe line 141 of the carrier gas supplier 140.

The pipe line 121 of the vaporizer 120 can be coupled to a discharge pump 190, and the discharge pump 190 can be coupled to a pipe line 111 of the reaction chamber 110.

The vaporizer 120 can be partitioned into first to third zones Z1 to Z3, and first to third heaters H1 to H3 can be provided in the first to third zones Z1 to Z3, respectively.

In the deposition apparatus constructed in such a manner, the chemicals of the chemical supplier 130 can be dissolved in a solvent such as ethanol, and then supplied to the vaporizer 120 through the pipe line 131 by a flow of carrier gas such as argon. At this time, the flow-rate controller 133 can serve to control the flow rate of the chemicals. In an embodiment, in the first zone Z1 of the vaporizer 120, liquid chemicals and gas chemicals can coexist. In the second zone Z2, particles can be filtered by a filter 125. The third zone Z3 can supply a gaseous source to the reaction chamber 110.

The reaction chamber 110 can receive the source to repeatedly supply the received source to the substrate (not shown) disposed within the reaction chamber 110, thereby depositing an atomic-layer thin film.

In an embodiment, in an deposition processes, polymer chemicals such as TEMAZr and TEMAHf can be easily decomposed even by a minute change in temperature. Therefore, when liquid-phase (mist or droplet) chemicals which are not perfectly vaporized pass through the filter, particles, powder, clogging or the like can occur in the vaporizer 120 and the peripheral devices thereof. In this case, a non-operation loss of the production apparatus can increase.

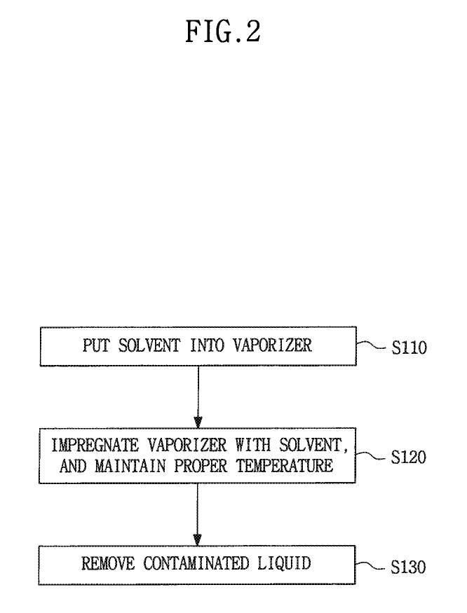

In an embodiment, it is possible to prevent the above-described problem by cleaning the vaporizer 120 and the peripheral devices thereof after the deposition process. Hereinafter, a method of cleaning the deposition apparatus according to an embodiment will be described. FIG. 2 is a flow chart sequentially showing a method of cleaning the deposition apparatus according to an embodiment. The method of cleaning the deposition apparatus can include putting a solvent into a vaporizer in S110; cleaning the vaporizer by impregnating the vaporizer with the solvent and constantly maintaining the cleaning temperature of the vaporizer in S120; and removing contaminated liquid which remains after cleaning the vaporizer in S130.

As the solvent first passes through the flow-rate controller before putting the solvent into the vaporizer, the flow-rate controller as well as the vaporizer can be cleaned, which makes it possible to effectively remove the above-described particles, powder, clogging, or the like. Furthermore, as the solvent passes through the pipe line of the carrier gas supplier before putting the solvent into the vaporizer, the pipe line of the carrier gas supplier can be cleaned, which makes it possible to effectively remove the above-described particles, powder, clogging, or the like.

In cleaning the vaporizer, the vaporizer can be impregnated with the solvent, and the cleaning temperature of the vaporizer can be constantly maintained, for example, at about 50 to about 90° C. In this step, the flow rate of the solvent can be set to about 250 to about 300 g/cycle. The cleaning process can be repeated, for example, the cleaning process can be performed at least three times.

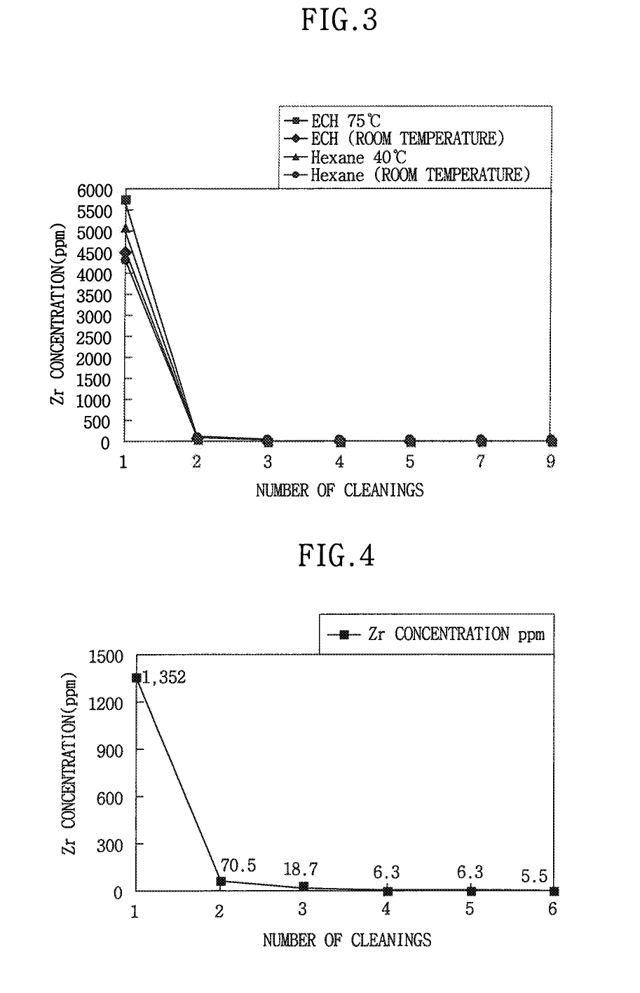

FIG. 3 is a graph showing an experiment for selecting an optimal solvent in the method of cleaning the deposition apparatus according to an embodiment. In this experiment, Ethyl Cyclo-hexane (ECH) and normal hexane have been used as the solvent in a state where the solvent is heated at a particular temperature. As shown in FIG. 3, in the case of ECH, the concentration of Zr at about 75° C. was higher than at room temperature, and in the case of normal hexane, the concentration of Zr at about 40° C. was higher than at room temperature. This indicates that cleaning efficiency has been improved at about 75° C. in the case of ECH and at about 40° C. in the case of normal hexane.

FIG. 4 is a graph showing the concentration of Zr versus the number of cleanings in the method of cleaning the deposition apparatus according to an embodiment. When the cleaning was performed once using Zr, the concentration of Zr was 1352 ppm. However, when the cleaning was performed three times, the concentration of Zr rapidly decreased to 70.5 ppm. This indicates that effective cleaning can be achieved by performing the cleaning only three times.

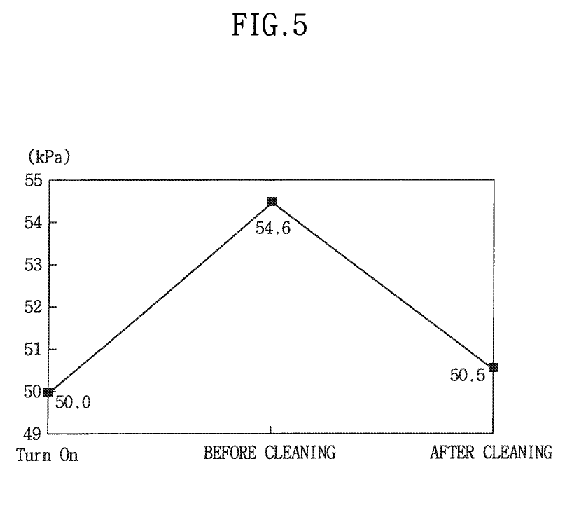

FIG. 5 is a graph illustrating a pressure change before and after the cleaning process in the method of cleaning the deposition apparatus according to an embodiment. The pressure of the vaporizer and the peripheral devices was maintained at about 54.6 kPa due to the particles, powder, and clogging occurring in the vaporizer and the peripheral devices, before the cleaning process. However, the pressure decreased to about 50.5 kPa after the deposition process. That is, the pressure of the vaporizer and the peripheral devices thereof increased to about 54.6 kPa due to the particle, powder, clogging, or the like before the cleaning process, but the particles, powder, clogging, or the like in the vaporizer and the peripheral devices were removed after the cleaning process. Therefore, the pressure of the vaporizer and the peripheral devices was adjusted into a proper deposition process condition.

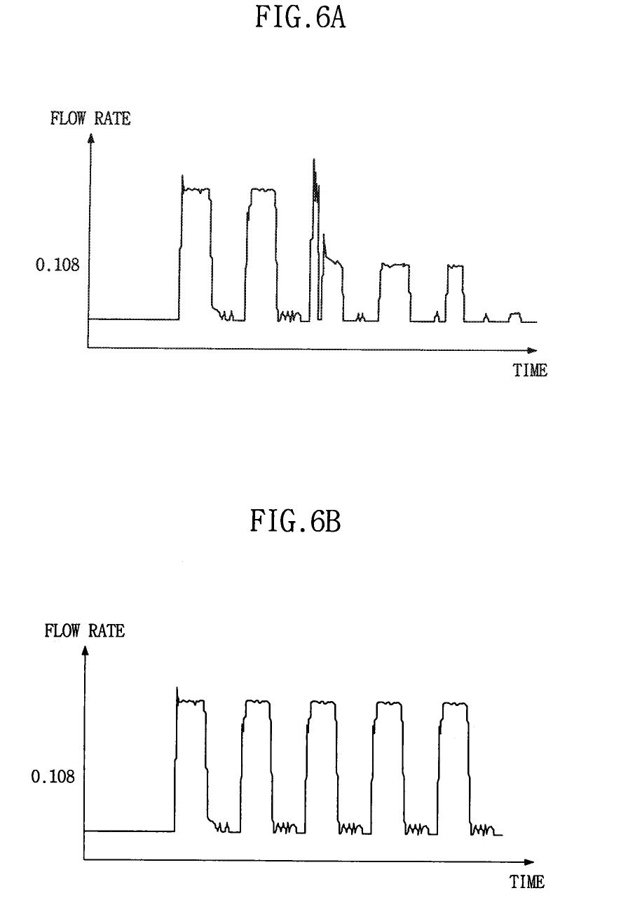

FIGS. 6A and 6B are graphs comparing the flow rate of chemicals in the related art with the flow rate of chemicals in an embodiment. In the related art as shown in FIG. 6A, since particles, powder, and clogging occur in the vaporizer and the peripheral devices during the deposition process, the flow rate of chemicals significantly decreases, and is destabilized. In an embodiment as shown in FIG. 6B, however, particles, powder, clogging, or the like do not occur or are reduced in the vaporizer or the peripheral devices, because the cleaning process is performed after the deposition process. Therefore, the flow rate of chemicals can be maintained.

In an embodiment, in a thin film deposition process such as a deposition process, a vaporizer for vaporizing chemicals and peripheral devices thereof are operated to supply a source to a reaction chamber. After the thin film deposition process, a cleaning process is performed, thereby removing particles, powder, and clogging which occur in the vaporizer and the peripheral devices thereof when a liquid source is phase-changed into a gaseous source. Therefore, it is possible to stabilize semiconductor production and to improve an operation rate of the deposition apparatus.

While example embodiments have been disclosed herein, it should be understood that other variations can be possible. Such variations are not to be regarded as a departure from the spirit and scope of example embodiments of the present application, and all such modifications as would be obvious to one skilled in the art are intended to be included within the scope of the following claims.

1. An atomic layer deposition (ALD) apparatus comprising:
a reaction chamber configured to deposit a thin film on a substrate;
a vaporizer coupled to the reaction chamber through a first pipe line to vaporize chemicals and to supply the vaporized chemicals to the reaction chamber;
a chemical supplier coupled to the vaporizer through a second pipe line to supply chemicals to the vaporizer; and
a solvent supplier coupled to the vaporizer through a third pipe line to clean the vaporizer by impregnating the vaporizer with a solvent after a thin film deposition process.

2. The ALD apparatus according to claim 1, wherein the second pipe line includes a flow-rate controller.

3. The ALD apparatus according to claim 1, wherein:
the chemical supplier is coupled to a chemical refill unit; and
the solvent supplier is coupled to a solvent refill unit.

4. The ALD apparatus according to claim 1, wherein
the second pipe line includes a flow-rate controller; and
the solvent supplier is coupled to the second pipe line at a location between the flow-rate controller and the chemical supplier.

5. The ALD apparatus according to claim 1, further comprising:
a carrier gas supplier coupled to the vaporizer through a fourth pipe line to supply carrier gases to the vaporizer;
wherein the solvent supplier is coupled to the fourth pipe line.

6. The ALD apparatus according to claim 1, wherein
the second pipe line includes a flow-rate controller; and
the solvent supplier is coupled to the second pipe line at a location between the flow-rate controller and the vaporizer.

7. The ALD apparatus according to claim 1, wherein the first pipe line coupled to a discharge pump.

8. The ALD apparatus according to claim 1, wherein the vaporizer is partitioned into first to third zones, and first to third heaters are provided in the first to third zones, respectively.

9. A method of cleaning a deposition apparatus, comprising:
putting a solvent into a vaporizer;
cleaning the vaporizer by impregnating the vaporizer with the solvent; and
removing contaminated liquid which remains after cleaning the vaporizer.

10. The method according to claim 9, further comprising maintaining a cleaning temperature of the vaporizer at a substantially constant temperature.

11. The method according to claim 9, wherein passing the solvent through a flow-rate controller to clean the flow-rate controller before putting the solvent into the vaporizer.

12. The method according to claim 9, wherein passing the solvent through a pipe line of a carrier gas supplier to clean the pipe line of the carrier gas supplier, before putting the solvent into the vaporizer.

13. The method according to claim 9, wherein in cleaning the vaporizer, the flow rate of the solvent is set to about 250 to about 300 g/cycle, and the cleaning is performed at least three times.

14. The method according to claim 9, wherein in cleaning the vaporizer, the temperature of the solvent is maintained at about 35 to about 80° C.

15. The method according to claim 9, further comprising providing the solvent to both a flow-rate controller coupled to the vaporizer and a pipe line coupled between a carrier gas supplier and the vaporizer.

16. A deposition apparatus comprising:
a vaporizer;
a chemical supplier;
a pipe line coupled between the vaporizer and the chemical supplier; and
a solvent supplier coupled to the pipe line.

17. The deposition apparatus of claim 16, further comprising:
a flow-rate controller disposed in the pipe line;
wherein the solvent supplier is coupled to the pipe line at a location between the chemical supplier and the flow-rate controller.

18. The deposition apparatus of claim 16, further comprising:
a flow-rate controller disposed in the pipe line;
wherein the solvent supplier is coupled to the pipe line at a location between the vaporizer and the flow-rate controller.

19. The deposition apparatus of claim 16, further comprising:
a flow-rate controller disposed in the pipe line;
wherein the solvent supplier is coupled to the pipe line at a first location between the chemical supplier and the flow-rate controller and at a second location between the vaporizer and the flow-rate controller.

20. The deposition apparatus of claim 16, the pipe line referred to as a first pipe line, the deposition apparatus further comprising:
a carrier gas supplier; and
a second pipe line coupled between the carrier gas supplier and the vaporizer;
wherein the solvent supplier is coupled to the second pipe line.
